(19) United States
(12) Patent Application Publication
(10) Pub. No.: US 2020/0319260 A1
(43) Pub. Date: Oct. 8, 2020

(54) Apparatus for and a Method of Detecting Leakage of Current

(71) Applicant: Exact Projects Limited, Holywell Flintshire (GB)

(72) Inventors: Peter Thomas Edward Hawkins, Cornwall (GB); Colin Benjamin Bathe, Cornwall (GB)

(73) Assignee: Exact Projects Limited, Holywell Flintshire (GB)

(21) Appl. No.: 16/304,224

(22) PCT Filed: May 9, 2017
(86) PCT No.: PCT/GB2017/051279

§ 371 Date: Nov. 23, 2018

(30) Foreign Application Priority Data
May 25, 2016 (GB) 1609192.8

(51) Int. Cl. G01R 31/52; G01R 19/00; G01R 19/15; G01R 19/165

(52) U.S. Cl. CPC G01R 31/52; G01R 19/16571; G01R 19/15; G01R 19/0007

(57) ABSTRACT

Apparatus (1) is for detecting electrical current in a support (2) for an overhead power line (3) adapted to carry AC electricity at a nominal frequency. The apparatus (I) comprises a first and a second electrical contact (16, 17). The first and second electrical contacts (16, 17) are adapted to be electrically coupled to the support (2) in spaced apart relationship, in use. A voltage detector (7) is coupled to the first and second contacts. A first voltage signal generator (11) is coupled to the first electrical contact (16) and is adapted to generate a voltage signal at a second frequency. A processor (15) is coupled to an output from the voltage detector (7). The voltage detector (7) is adapted to detect a first voltage differential between the first and second electrical contacts (16, I 7) at a first frequency corresponding to the nominal frequency, and to detect a second voltage differential between the two electrical contacts (16, 17) at the second frequency. The processor (15) receives the first and second voltage differentials, and the processor (15), dependant on the detected first and second voltage differentials, generates an output signal indicative of the presence of an electrical current in the support (2).

The invention relates to apparatus for and a method of detecting leakage of current, and especially, current leakage in a support, such as a wooden pole, for supporting a power line.

Wooden poles are frequently used to support overhead powerlines. Wood is normally an insulator and the power lines are suspended from the pole using electrical insulators. Hence, in normal circumstances there is minimal leakage of electrical current from the power line to earth through the pole.

However, in older installations the electrical insulators between the power lines and the pole may have degraded compromising the electrical insulation properties of the insulation system. The compromised integrity of the pole's safety may be due to dereliction or damage to any part of the insulators combined with increased conduction in the pole (e.g. due to water logging, contamination or rot). In these circumstances, leakage currents can pass from the power supply lines into the pole. If a human or animal touches the pole such leakage currents can cause injury or even death if the leakage current is sufficiently high.

A number of devices exist that measure voltage on the pole. In these devices small levels of leakage are detected as a voltage gradient across the pole and can be measured by an appropriate device. However, the fundamental issue of voltage-only measurement is that it does not take into account the condition of the pole itself.

A very dry pole with minimal current leakage may produce a voltage reading of half the power supply line voltage at a point half way down the pole. A wet pole with substantial current leakage could also produce the same reading at the same position. In these two situations, the first condition may not be a cause for concern but the second condition would likely be hazardous and require cautious inspection of the pole and remedial action to be taken.

In addition, a further potential problem with inspections using hand-held devices is that they are highly dependent on the condition of the pole and the weather conditions when inspection is carried out. For example, the pole could become water-logged and hazardous during wet conditions but during dry weather conditions it could dry out and cease to be hazardous. Therefore, a pole that is actually hazardous could be identified as not being hazardous if it is inspected using a conventional device during dry conditions.

In accordance with a first aspect of the present invention, there is provided apparatus for detecting electrical current in a support for a power line adapted to carry AC electricity at a nominal frequency, the apparatus comprising a first and a second electrical contact, the first and second electrical contacts being adapted to be electrically coupled to a support in spaced apart relationship, in use; a voltage detector coupled to the first and second contacts; a first voltage signal generator coupled to the first electrical contact and adapted to generate a voltage signal at a second frequency; and a processor coupled to an output from the voltage detector; and wherein the voltage detector is adapted to detect a first voltage differential between the first and second electrical contacts at a first frequency corresponding to the nominal frequency, and to detect a second voltage differential between the two electrical contacts at the second frequency, the processor receiving the first and second voltage differentials, and the processor, dependant on the detected first and second voltage differentials, generating an output signal indicative of the presence of an electrical current in the support.

In accordance with a second aspect of the present invention, there is provided a method of detecting electrical current in a support for a power line, the method comprising detecting a first voltage differential between two spaced apart electrical contacts on the support at a first frequency corresponding to the nominal frequency of electrical power carried by the power line; applying a voltage signal to a first of the electrical contacts at a second frequency and detecting a second voltage differential between the two electrical contacts at the second frequency; and dependant on the detected first and second voltage differentials, generating an output signal indicative of an electrical current in the support.

Typically, the apparatus also includes an output device which in response to receipt of an output signal from the processor, generates an indication of the presence of an electrical current in the support.

In one example, the processor, may only generate an output signal if the detected first and second voltage differentials indicate that the electrical current in the support is equal to or above a threshold value.

Typically, the apparatus may further comprise a first resistor in parallel with the electrical contacts during detection of the first voltage differential. Preferably the first resistor is a variable resistor and most preferably the magnitude of the resistance of the first resistor is selected by the processor, typically in response to a detected first voltage.

Typically, the apparatus may further comprise a second resistor in series with the electrical contacts and the first voltage signal generator during detection of the second voltage differential. Preferably the second resistor is a variable resistor and most preferably the magnitude of the resistance of the second resistor is selected by the processor, typically in response to a detected second voltage.

The processor may determine an impedance of the support using the first and second voltage differentials. Preferably, the impedance of the support is determined also using the magnitude of the second resistor at the detected second voltage differential.

Preferably, the electrical current in the support is determined by the processor using at least the impedance of the support and the first voltage differential. The electrical current may be determined by calculation or by use of a first look-up table.

The processor may generate an output signal if at least one of (a) the impedance of the support; and (b) the electrical current in the support are outside certain limits. The limits may be a predetermined threshold or thresholds and may be stored in a memory device. The limits may be in the form of a second look-up table. The processor may compare the impedance of the support and the current in the support with the contents of the second look-up table. As a result of the comparison the processor may then determine whether to generate an output signal.

Preferably, the output device comprises a visual indicator to indicate the current between the two contacts. Most preferably, the indicator is a mechanical indicator, such as a flag, that may be triggered by an output signal received from the processor. Most preferably, the mechanical indicator is movable between a first position and a second position, the second position indicating that the current between the two contacts is greater than or equal to a threshold level and the first position indicating that the current is less than the threshold level.

Preferably, the voltage detector comprises a differential amplifier.

Typically, the second frequency may be several times the nominal frequency and preferably, the second frequency is at least an order of magnitude greater than the nominal frequency of the electricity in the power line. For example, if the nominal frequency is less than 100 Hz, the second frequency of is preferably at least 500 Hz, and more preferably approximately 1 kHz or greater.

Preferably, the processor includes first and second filters to filter a combined voltage differential from the voltage detector to obtain the first and second voltage differentials, respectively, before the signals are analysed by the processor. Preferably, the first and second filters filter the combined voltage differential by use of reference frequencies which are at least approximately equal to the nominal frequency and the second frequency, respectively. In the case of the second voltage differential, the reference frequency may be the voltage signal from the first signal generator.

In the case of the first voltage differential, the reference frequency may be generated by a second signal generator having a frequency approximately equal to a nominal frequency of the voltage to be detected. Preferably, the reference frequency generated by the second signal generator is a reference frequency band and typically, the reference frequency band is centred around the nominal frequency. The reference frequency band typically has a bandwidth of less than or equal to 2 Hz and preferably, the frequency band has width of approximately 1 Hz. In one example of the invention, where the nominal frequency is 50 Hz, the reference frequency band is 49.5 Hz to 50.5 Hz. In another example of the invention, where the nominal frequency is 60 Hz, the reference frequency band is 59.5 Hz to 60.5 Hz.

In one example of the invention, the filter may comprise a Goertzel algorithm.

In one example of the invention, the processor may comprise additional filters to filter harmonics of the nominal frequency to obtain harmonic voltage differentials corresponding to harmonic frequencies of the nominal frequency. For example, if the nominal frequency of the electricity in the power lines is 50 Hz, additional filter(s) could be used to filter additional detected voltage differentials at harmonics of 100 Hz, 150 Hz, 200 Hz, 250 Hz, etc. It is also possible that only certain additional harmonics may be filtered. For example, the additional filter(s) could be at only 150 Hz. In this case additional signal generators may also be provided to provide reference frequencies to the additional filters at the harmonic frequencies to be filtered. Preferably the additional reference frequencies are frequency bands with a spread that may be similar to the frequency band generated by the second signal generator.

Typically, the apparatus may further comprise an impedance, such as a resistor, between one electrical contact and an input of the voltage detector. Typically, the impedance acts as a current limiting resistor to protect the voltage detector and other components of the apparatus from excess current at the contact.

In one example of the invention, the apparatus could include a built-in power supply, such as batteries. Alternatively, the power supply could be external of the apparatus and electrically coupled to the apparatus by a suitable electrical coupling device.

Typically, the support may be formed from a material that is normally not an electrical conductor, such as a material that is an insulator under normal circumstances. For example, the material of the support could be wood. The support may be used to support an electrical overhead line or overhead cable. The overhead line may be, for example, any overhead part of a system for distribution of electrical power to an end user or for supply of electrical power to a vehicle, such as a train, trolleybus or tram.

An example of apparatus for detecting current in a support for electrical power lines in accordance with the invention will now be described with reference to the accompanying drawings, in which:

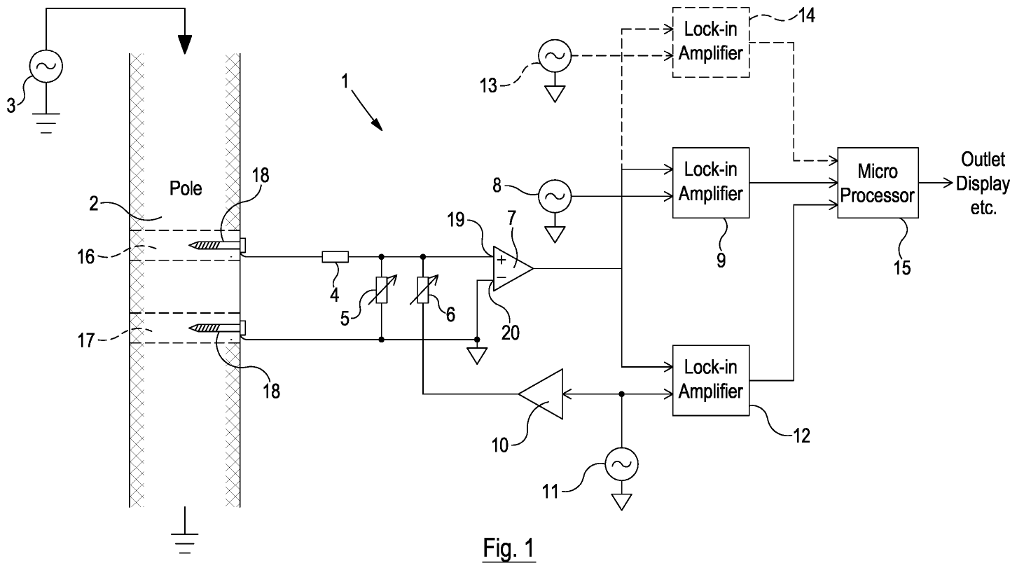

FIG. 1 is a schematic block diagram of a current monitoring device for detecting current leakage in a wooden utility pole;

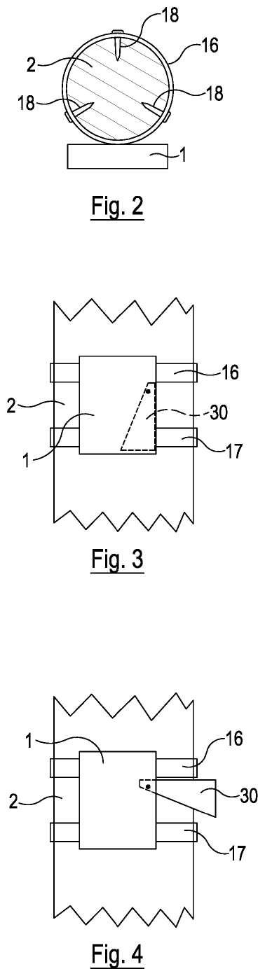

FIG. 2 is a cross-sectional view of a pole showing a circumferential electrode with the current monitoring device attached;

FIG. 3 shows part of a pole with the current monitoring device attached and an indicator flag in a first position; and

FIG. 4 is a similar view to the view of FIG. 3 but with the indicator flag in a second position.

FIG. 1 is a schematic block diagram of a utility pole 2 for supporting high voltage power lines indicated schematically by oscillator 3. The utility pole 2 is a wooden pole and the pole is shown in FIG. 1 as a longitudinal section. The high voltage power lines 3 supported by the pole 2 are mounted on the pole 2 via electrical insulators (not shown) to minimise the risk of current leakage from the power lines 3 to the pole 2. Typically, the voltage carried by the power lines 3 is of the order of a few kilovolts. For example, in the UK overhead power lines supported by wooden poles typically carry electrical power at voltages of 6.6 kV or 11 kV. The power lines supported by wooden poles in other countries generally carry electrical power at similar voltages.

In the UK and most European countries, the frequency of the AC voltage in the power supply line 3 is 50 Hz. However, in other countries the frequency may be different, such as 60 Hz in North America. In the example described, it is assumed that the frequency of the voltage on the power supply lines is 50 Hz. However, for other countries using a different nominal frequency, such as 60 Hz, the current monitoring device can be modified to operate at 60 Hz by changing the components that operate specifically at 50 Hz, as described below, to components that operate at the different nominal frequency, such as 60 Hz.

As shown in FIGS. 1 and 2 a current monitoring device 1 is attached to two spaced apart electrical contacts 16, 17 that each extend circumferentially around the pole 2 and are fixed to the pole 2 using fasteners 18. The fasteners 18 are typically metal and are preferably long enough to penetrate through the skin of the pole into the core of the wood forming the pole 2. The fasteners may be in the form of metal nails or screws.

As the pole 2 cannot be considered as homogeneous in a radial direction, errors can be caused by merely taking electrical measurements at the surface of the pole. Therefore, an advantage of using metallic fasteners 18 together with the circumferential contacts 16, 17 is that more reliable electrical detection can be achieved. Typically, the contacts 16, 17 are spaced apart by at least approximately 100 mm.

FIG. 1 shows a schematic block diagram of the electronics located within the monitoring device 1 and that are electrically coupled to the contacts 16, 17. A differential amplifier 7 is connected across the contacts 16, 17 and is connected to the contact 16 via a current limiting resistor 4. A variable load resistor 5 is connected in parallel with inputs 19, 20 of the differential amplifier 7 across the contacts 16, 17. The resistor 4 and the variable resistor 5 effectively form an attenuator. The variable load resistor 5 is used to reduce the voltage across the contacts 16, 17 down to a level which can be measured by the differential amplifier 7. If the voltage across the contacts 16, 17 is high, the value of the variable resistor 5 is adjusted to a low value by the micro-processor 15, thereby giving substantial attenuation of the voltage signal received by the amplifier 7. The input signal from the pole 2 could cover a large range of voltages, for example, from approximately 0.1V to 300V AC RMS. In practice, the variable load resistor 5 may be formed from a set of discreet fixed resistors and measurements are made with each resistor connected in turn. This is controlled by the micro-processor 15 via a control signal line (not shown). Therefore, multiple measurements are made using the differential amplifier 7 with the variable load resistor 5 set to different resistances. According to the scale of the voltage across the contacts 16, 17 some voltage measurements will be void (or discarded) due to being under range or over range. The acceptable signals for the differential amplifier 7 and the micro-processor 15 are constrained by an upper limit of the internal operating voltage of the devices 7, 15 and a lower limit of resolution of the analogue to digital converter (not shown) occurring at the interface of the differential amplifier 7 and the micro-processor 15. A typical range of operating voltages may be from approximately 1 mV at the lower limit to approximately 3V at the upper limit.

The differential amplifier 7 takes as inputs the attenuated voltage across the contacts 16, 17 and outputs the difference between the two voltages. Hence, the output from the differential amplifier 7 is the differential voltage between the circumferential electrical contacts 16, 17. This differential voltage is indicative of the voltage gradient in a longitudinal direction along the pole 2.

The output from the amplifier 7 is connected to a filter 9 and a filter 12. The filters 9, 12 are shown as discreet blocks in FIG. 1 for reasons of clarity and explanation. However, in practice they are implemented as part of the micro-processor 15. The filters in 9, 12 function in the same manner as lock-in amplifiers and are implemented in the micro-processor 15 using a Goertzel algorithm. The filter 9 also receives a 50 Hz reference signal from the 50 Hz oscillator 8. The reference signal from the oscillator 8 is a frequency band signal centred on 50 Hz with a width of 1 Hz. Hence, the reference frequency band from the oscillator 8 is from 49.5 Hz to 50.5 Hz.

The filter 12 receives a reference frequency from a 1 kHz local oscillator 11 that produces a signal with a constant amplitude. In addition to providing a reference frequency signal to the filter 12, the output from the oscillator 11 is also output to amplifier 10 which feeds an amplified signal from oscillator 11 through a variable driving resistor 6 to the positive input 19 of the amplifier 7 and via the current limiting resistor 4 to contact 16. The amplified signal from the oscillator 11 that is fed to contact 16 is then picked up by contact 17 and fed to the negative input 20 of the amplifier 7. The amplifier 7 then outputs the difference between the voltages of the amplified signal produced by the oscillator 11 between the two contacts 16, 17 as an output. The difference between the 1 kHz at input 19 and input 20 of the amplifier 7 is indicative of the voltage drop between the contacts 16, 17 and therefore, of the impedance of the pole 2 between contacts 16, 17. In particular, the lower the differential voltage of the 1 kHz signal that is output by the amplifier 7 then the less impedance the pole 2 has and the more conductive it is.

The differential voltage output from the differential amplifier 7 is a combined differential voltage across all frequencies, including the nominal 50 Hz frequency of the electricity in the power supply lines 3, any harmonic frequencies of the 50 Hz nominal frequency that may be present and the 1 kHz frequency from the local oscillator 11.

Because the filter 9 acts as a lock-in amplifier with a reference frequency of 50 Hz from the oscillator 8, the filter 9 will pass the differential voltage signal from the amplifier 7 at between 49.5 Hz to 50.5 Hz and block all other frequencies. Hence, noise at other frequencies is blocked by the filter 9 and the 1 kHz voltage signal is also blocked by the filter 9. Therefore, the differential voltage signal passed by the filter 9 is only that relating to the 50 Hz component and is indicative of the amount of voltage from the power lines 3 that is in the pole 2.

As the filter 12 uses the 1 kHz reference signal, the filter 12 will pass the 1 kHz differential voltage signal output by the amplifier 7 but will block all other frequencies. Hence, the filter 12 will block any noise in the signal and will also block 50 Hz differential voltage signal. Therefore, the differential voltage signal passed by the filter 12 is only that relating to the 1 kHz component and is indicative of the impedance of the pole 2.

Therefore, the micro-processor 15 receives from the filter 9 a relatively clean 50 Hz differential voltage signal generated by the amplifier 7 and receives from the filter 12 a relatively clean 1 kHz voltage differential signal generated by the amplifier 7. The micro-processor 15 then analyses these signals which represent the voltage gradient of the power supply voltage in the pole 2 and the impedance of the pole 2 to determine whether the leakage current passing down through the pole 2 is potentially hazardous.

As the 50 Hz differential signal passed by the filter 9 is indicative of the voltage gradient through the pole 2 and the 1 kHz differential voltage signal from the filter 12 is indicative of the impedance of the pole 2. Therefore, because current equals voltage divided by impedance (I=V/Z), the micro-processor can analyse the output signals from the filters 9, 12 to obtain an indication of whether the current passing down through the pole 2 is potentially hazardous.

In order to assess whether the signals received from the filters 9, 12 indicate a hazardous leakage current, the micro-processor 15 calculates the resistance of the pole 2 between the electrical contacts 16, 17 using the differential voltage signals and the magnitudes of the resistor 4 and the value of the resistor 6 corresponding to the 1 kHz differential voltage signal using the following equation derived from Ohms Law:

R_{P}=V₅₀(R₄+R₆)/(V₁ₖ−V₅₀)

where R_{P} is the resistance of the pole 2 in Ohms, V₅₀ is the differential voltage signal from the filter 9 in Volts, V₁ₖ is the differential voltage signal from the filter 12 in Volts, R₄ is the resistance of the resistor 4 in Ohms and R₆ is the resistance of the resistor 6 in Ohms.

Using the calculated value of R_{P}, the value of V₅₀ and the resistance of resistor 5 at V₅₀, the micro-processor 15 can assess whether the current in the pole 2 is above or below a threshold level and therefore, indicates a potential hazardous leakage current. This assessment can be performed by the processor either by calculation or by comparing the values with a look-up table that may be loaded into the micro-processor 15. The use of the resistance of resistor 5 is advantageous in this assessment as the resistance of resistor 5 when the 50 Hz differential voltage was measured indicates the attenuation of the 50 Hz differential voltage and hence, the actual value of the 50 Hz voltage between the contacts 16, 17.

If a look-up table is used this may be based on previously executed computations. An example of a suitable look-up table may be arranged to have “pages” based on the 50 Hz differential voltage from the filter 9 combined with the resistance of resistor 5 used to obtain the 50 Hz differential voltage signal. The processor would then select the pole current value corresponding to the calculated resistance of the pole 2 (R_{P}).

The final determination of the degree of hazard may be carried out by access to a table of limits. The table of limits is an array of possible pole currents and resistances of the pole 2. For example, a higher current in a very low impedance pole may be considered safer than a similar current in a high impedance pole. For example, a current of 500 μA may be considered borderline hazardous in a pole whose resistance is less than 40 kΩ. However, a current of 100 μA may be considered dangerous in a pole whose resistance is 100 MΩ. These values are indicative only and actual values in the realm of 100 μA to 5 mA may apply to poles of resistance between 10 kΩ and 500 MΩ.

If as a result of evaluating the signals from the filters 9, 12 using the resistances of the resistors 4, 5, 6, the micro-processor 15 determines that the leakage current in the pole 2 is potentially hazardous, then the processor 15 outputs a signal to a mechanical flag 30 which triggers the flag 30 to move from the position shown in FIG. 3 to the position shown in FIG. 4. This indicates to anyone approaching the pole 2 that a potentially hazardous leakage current has been detected in the pole 2 by monitoring device 1. Alternatively, the indicator could be a movable element within the casing of the device 1 that is visible through a window in the casing. For example, the moveable element may have two sections of different colours such as green and red. When no potentially hazardous leakage current has been detected the green section may be visible through the window. When a potentially hazardous leakage current is detected, the output signal from the micro-processor 15 causes the moveable element to move so that the red section is visible through the window. In other examples of the invention, any suitable notification device could be used. This could for example, be a non-mechanical visual notification device, such as a light (for example, a light emitting diode (LED)) and/or audible notification device, such as a buzzer or other audible alarm device.

The advantage of using a mechanical flag 30 to indicate visually that a potentially dangerous leakage current has been detected in the pole 2 is that after the triggering of the flag 30, no more power is required to maintain the flag 30 in the triggered position. For example, the flag 30 could be spring-loaded and retained in the closed position shown in FIG. 3 by a catch (not shown). The catch can then be released by an output signal from the micro-processor 15 indicating a potentially hazardous leakage current in the pole 2.

In one example of the invention, the electronics described above of the device 1 can be powered by an in-built power source, such as a battery which may or not be replaceable. Alternatively, the power source could be separate from the device 1, such as a separate battery pack or other external power supply that is electrically connected to the device 1 to power the device 1.

In addition, the device 1 could also be modified to additionally detect harmonics of the nominal frequency of the power supply lines 1 using additional filters 14 and additional oscillators 13, shown in phantom in FIG. 1. When the nominal frequency of the power supply line is 50 Hz, the typically the additional oscillators 13 could have frequencies of 100 Hz, 150 Hz, 200 Hz, etc., In certain instances, certain harmonics may be more desirable to detect than other harmonics so, for example, there may not be provided a 100 Hz filter but instead a 150 Hz filter and 150 Hz oscillator. The outputs of the additional filters 14 also feed into the micro-processor 15 which also uses the outputs from the additional filters 14 to assist in assessing whether leakage current detected in the pole 2 is potentially hazardous.

An advantage of using 1 kHz oscillator 11 is that the 1 kHz frequency of the signal applied to the contact 16 is significantly higher than the 50 Hz frequency of the power line 3. Hence, by using the filters 9, 12 it is possible to use the same differential amplifier 7 to calculate the 50 Hz voltage differential between contacts 16, 17 and to measure the difference between the applied and received 1 kHz signal. This also means that it is possible to conduct both measurements simultaneously.

Another advantage of the invention is that it enables utility pole 2 to be monitored to determine whether potentially dangerous leakage current is passing through the pole 2 and to trigger a visual display that will continue to be displayed even if the conditions within the pole change and the leakage current reduces to a level where it is no longer potentially dangerous. The invention also enables a person to identify whether pole 2 has or has had a potentially dangerous leakage current without having to touch the pole 2.

1-29. (canceled)

30. Apparatus for detecting electrical current in a support for an overhead power line adapted to carry AC electricity at a nominal frequency, the apparatus comprising a first and a second electrical contact, the first and second electrical contacts being adapted to be electrically coupled to a support in spaced apart relationship, in use; a voltage detector coupled to the first and second contacts; a first voltage signal generator coupled to the first electrical contact and adapted to generate a voltage signal at second frequency; and a processor coupled to an output from the voltage detector; and wherein the voltage detector is adapted to detect a first voltage differential between the first and second electrical contacts at a first frequency corresponding to the nominal frequency, and to detect a second voltage differential between the two electrical contacts at the second frequency, the processor receiving the first and second voltage differentials, and the processor, dependant on the detected first and second voltage differentials, generating an output signal indicative of the presence of an electrical current in the support.

31. Apparatus according to claim 30, further comprising an output device which in response to receipt of the output signal from the processor, generates an indication of the presence of an electrical current in the support.

32. Apparatus according to claim 30, wherein the processor only generates an output signal if the detected first and second voltage differentials indicate the electrical current in the support is equal to or above a threshold value.

33. Apparatus according to claim 30, wherein the output device comprises a visual indicator to indicate the current between the two contacts.

34. Apparatus according to claim 33, wherein the indicator is a mechanical indicator.

35. Apparatus according to claim 33, wherein the mechanical indicator is triggered by the output signal received from the processor.

36. Apparatus according to claim 30, wherein the voltage detector comprises a differential amplifier.

37. Apparatus according to claim 30, wherein a first voltage signal generator generates the second frequency at least several times the nominal frequency.

38. Apparatus according to claim 37, wherein the second frequency is at least an order of magnitude greater than the nominal frequency of the electricity in the power line.

39. Apparatus according to claim 30, further comprising first and second filters to filter a combined voltage differential from the voltage detector to obtain the first and second voltage differentials, respectively.

40. Apparatus according to claim 39, wherein the first and second filters filter the combined voltage by use of first and second reference frequencies, respectively, which are at least approximately equal to the nominal frequency and the second frequency, respectively.

41. Apparatus according to claim 39, wherein at least one of the first and second filters has the functionality of a lock-in amplifier.

42. Apparatus according to claim 39, wherein at least one of the filters comprises a Goertzel algorithm.

43. Apparatus according to claim 39, further comprising at least one additional filter to filter at least one harmonic of the nominal frequency to obtain at least one harmonic voltage differential.

44. A method of detecting electrical current in a support for an overhead power line, the method comprising detecting a first voltage differential between two spaced apart electrical contacts on the support at a first frequency corresponding to the nominal frequency of electrical power carried by the power line; applying a voltage signal to a first of the electrical contacts at a second frequency and detecting a second voltage differential between the two electrical contacts at the second frequency; and dependant on the detected first and second voltage differentials, generating an output signal indicative of an electrical current in the support.

45. A method according to claim 44, wherein the output signal is only generated if the detected first and second voltage differentials indicate the electrical current in the support is equal to or above a threshold value.

46. A method according to claim 44, wherein the second frequency is at least several times the nominal frequency.

47. A method according to claim 44, wherein the detecting of the first and second voltage differentials comprises detecting between the two electrical contacts a combined voltage differential over a frequency spectrum comprising the first and second frequencies, and filtering the composite voltage differential to obtain the first and second voltage differentials.

48. A method according to claim 47, wherein the combined voltage differential is filtered by first and second filters to obtain the first and second voltage differentials, respectively; and the first and second filters filter the combined voltage differential by use of first and second reference frequencies, respectively, which are at least approximately equal to the nominal frequency and the second frequency, respectively.

49. A method according to claim 48, further comprising an additional filter to filter the combined voltage differential at a harmonic of the nominal frequency to obtain a third voltage differential; and the additional filter filters the combined voltage signal by use of a third reference frequency, the third reference frequency corresponding to the harmonic of the nominal frequency.
